(19) United States
(12) Patent Application Publication
(10) Pub. No.: US 2016/0097881 A1
(43) Pub. Date: Apr. 7, 2016

(54) ANTI-REFLECTION STRUCTURE AND DISPLAY DEVICE

(71) Applicant: InnoLux Corporation, Jhu-Nan (TW)

(72) Inventors: Yi-Xin YANG, Jhu-Nan (TW); Cheng-Hsu CHOU, Jhu-Nan (TW)

(21) Appl. No.: 14/873,944

(22) Filed: Oct. 2, 2015

(30) Foreign Application Priority Data
Oct. 2, 2014 (TW) 103134454

(51) Int. Cl. G02B 1/08; H01L 51/00; G02B 5/30

(52) U.S. Cl. CPC G02B 1/08; G02B 5/3083; G02B 5/3041; H01L 51/0097

(57) ABSTRACT

A display device is disclosed. The display device includes a display unit and an anti-reflection structure. The anti-reflection structure is disposed on one side of the display unit and includes a first barrier layer, a phase retardation film, a second barrier layer, a polarizing film and a covering layer. The first barrier layer is disposed on the display unit. The phase retardation film is disposed on the first barrier layer. The second barrier layer is disposed on the phase retardation film. The polarizing film is disposed on the second barrier layer. The covering layer is disposed on the polarizing film.

### CROSS REFERENCE TO RELATED APPLICATIONS

This Non-provisional application claims priority under 35 U.S.C. §119(a) on Patent Application No(s). 103134454 filed in Taiwan, Republic of China on Oct. 2, 2014, the entire contents of which are hereby incorporated by reference.

### BACKGROUND

1. Technical Field

The present invention relates to a display device and, in particular, to an anti-reflection structure of a display device.

2. Related Art

The common display devices include liquid crystal display devices and organic light emitting diode (OLED) display devices. In the conventional art for manufacturing a display device, a glass substrate is adopted to cover the liquid crystal display or the organic light emitting diode display. In other words, the outmost covering layer of the conventional display device is a glass substrate (a cover), which can provide good water-vapor-proof and oxygen-proof properties. However, in order to satisfy the user's demand for easy carrying, the conventional glass substrate has been replaced by a plastic cover plate so as to reduce the entire weight of the display device. Unfortunately, the moisture can directly penetrate through the plastic cover plate and then damage the internal components of the display.

In general, the dam seal is provided around the display device for adhering and sealing the cover and the substrate of the display unit. This configuration can prevent the moisture to enter the internal space of the display device through the bonding portion of the cover and the substrate of the display unit. However, this approach can not prohibit the moisture to penetrate through the plastic cover plate, so the moisture may reach the internal space of the display device through the display surface of the display device.

In addition, regarding to the OLED display device, the selected materials of the OLED display device allow the OLED display device becomes flexible. However, when the cover is sealed by the conventional dam seal, the flexible property of the OLED display device will be suffered.

Moreover, the light source of the OLED display device is a self-luminous organic material, and the OLED display device includes a reflective electrode for centralizing and reflecting the emitted light of the self-luminous organic material and emitting the light out the display area. In the circumstance of strong light, the environment light entering the OLED display device will also be reflected to the display area of the OLED display device, which causes the decrease of the contrast of the display area so as to make the displayed image unclear. In general, an anti-reflection structure is provided at the display side of the OLED display device for adjusting the polarizing direction and phase difference of the incident environmental light, thereby blocking the reflection of the environmental light so as to decline the unclear issue of the displayed image. However, the conventional anti-reflection structure cannot stop moisture and oxygen entering the internal space of the display device.

### SUMMARY

In view of the foregoing, an objective of the present invention is to provide an anti-reflection structure and a display device that can prevent the moisture and oxygen from entering the internal space of the display device by the covering layer and barrier layer of the anti-reflection structure. In addition, the anti-reflection structure has specific material and structure composition, so it can achieve the effects of water-vapor-proof, oxygen-proof and flexible.

To achieve the above objective, an embodiment of the present invention discloses a display device including a display unit and an anti-reflection structure. The anti-reflection structure is disposed at one side of the display unit and includes a first barrier layer, a phase retardation film, a second barrier layer, a polarizing film and a covering layer. The first barrier layer is disposed on the display unit. The phase retardation film is disposed on the first barrier layer. The second barrier layer is disposed on the phase retardation film. The polarizing film is disposed on the second barrier layer. The covering layer is disposed on the polarizing film.

To achieve the above objective, another embodiment of the present invention also discloses an anti-reflection structure including a first barrier layer, a phase retardation film, a second barrier layer, a polarizing film and a covering layer. The first barrier layer is disposed on a display unit. The phase retardation film is disposed on the first barrier layer. The second barrier layer is disposed on the phase retardation film. The polarizing film is disposed on the second barrier layer. The covering layer is disposed on the polarizing film.

In one embodiment, the first barrier layer and the second barrier layer are made of inorganic material.

In one embodiment, at least one of the first barrier layer and the second barrier layer is made of diamond-like carbon (DLC).

In one embodiment, the second barrier layer includes a first sub-barrier layer, a second sub-barrier layer, and an adhesive layer disposed between the first sub-barrier layer and the second sub-barrier layer.

In one embodiment, the first sub-barrier layer is formed on the polarizing film, and the second sub-barrier layer is formed on the phase retardation film.

In one embodiment, the first barrier layer includes a combination of a higher stress layer and a lower stress layer.

In one embodiment, the second barrier layer includes a combination of a higher stress layer and a lower stress layer.

In one embodiment, the higher stress layer is made of inorganic material, and the lower stress layer is made of organic material.

In one embodiment, the display unit is an organic light emitting diode (OLED) display unit.

In one embodiment, the thickness of the first barrier layer and the second barrier layer is between 0.1 μm and 5 μm.

As mentioned above, in the anti-reflection structure, the first barrier layer is disposed on one side of the phase retardation film opposite to the display unit, and the second barrier layer is disposed on one side of the polarizing film opposite to the display unit. In more detailed, the first barrier layer is disposed on a display unit, the phase retardation film is disposed on the first barrier layer, the second barrier layer is disposed on the phase retardation film, the polarizing film is disposed on the second barrier layer, and the covering layer is disposed on the polarizing film. In other words, the polarizing film, the second barrier layer, the phase retardation film and the first barrier layer are configured between the covering layer and the display unit so as to form the anti-reflection structure with multiple water-vapor-proof and oxygen-proof structures (including the covering layer, the first barrier layer and the second barrier layer). The first and second barrier layers are disposed on the polarizing film and the phase retardation film, respectively, so that it is possible to enhance the water-vapor-proof and oxygen-proof abilities of the anti-reflection structure. Moreover, the anti-reflection structure is disposed at one side of the display unit, so that it can prevent moisture and oxygen from entering the internal space of the display unit through the display surface, thereby protecting the internal components of the display unit from damages.

In addition, the polarizing film and the phase retardation film of the anti-reflection structure can adjust the polarizing direction and phase difference of the light entering the display unit, thereby blocking the reflection of the environmental light so as to decline the unclear issue of the displayed image.

### BRIEF DESCRIPTION OF THE DRAWINGS

The embodiments will become more fully understood from the detailed description and accompanying drawings, which are given for illustration only, and thus are not limitative of the present invention, and wherein:

FIG. 1A is a sectional view of a display device according to an embodiment of the invention;

FIG. 1B is a sectional view of a display device according to another embodiment of the invention;

FIG. 2 is a sectional view of an anti-reflection structure according to another embodiment of the invention;

FIG. 3 is a sectional view of an anti-reflection structure according to another embodiment of the invention; and

FIG. 4 is a sectional view of an anti-reflection structure according to another embodiment of the invention.

### DETAILED DESCRIPTION OF THE INVENTION

The embodiments of the invention will be apparent from the following detailed description, which proceeds with reference to the accompanying drawings, wherein the same references relate to the same elements.

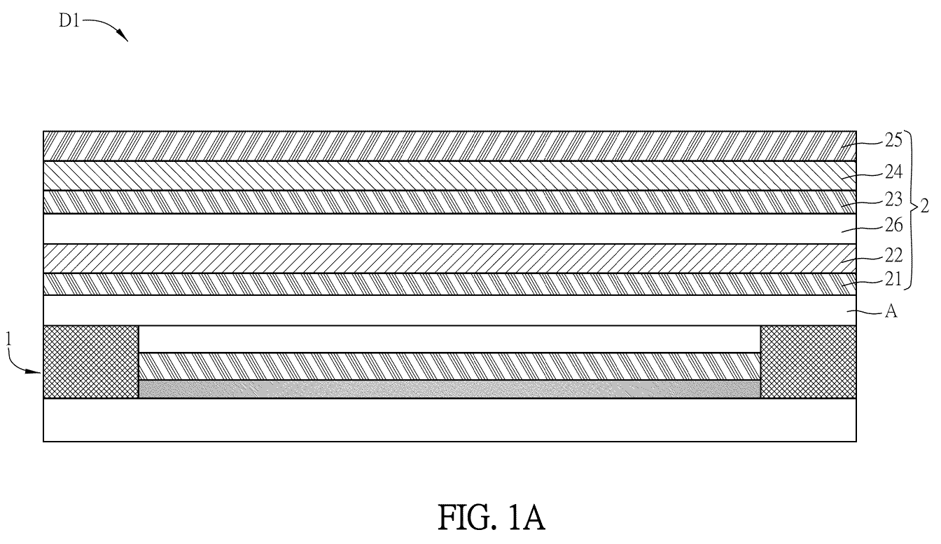

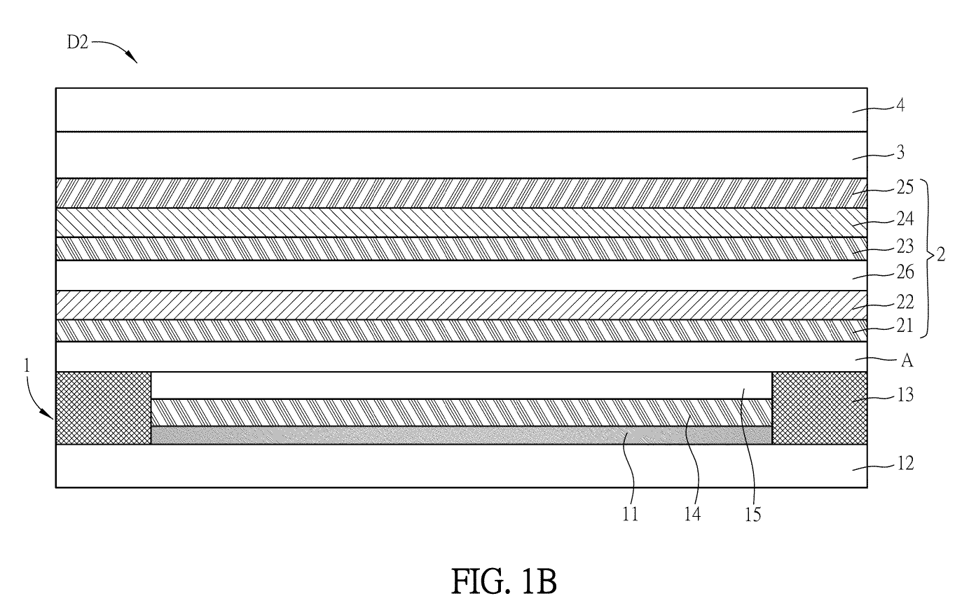

FIG. 1A is a sectional view of a display device D1 according to an embodiment of the invention. Referring to FIG. 1A, the display device D1 of the embodiment is, for example but not limited to, a liquid crystal display (LCD) device, a LED display device, an OLED display device or an electrophoretic display device.

The display device D1 of the embodiment includes a display unit 1 and an anti-reflection structure 2. The anti-reflection structure 2 is disposed at one side of the display unit 1, which is the display surface. That is, the light emitted from the light source of the display unit 1 can be outputted through the display surface. Corresponding to the above-mentioned aspects of the display device D1, the display unit 1 can be an LCD panel, an LED display panel, an OLED display panel, or an electrophoretic display panel. In these following illustrations, the display unit 1 is an OLED display panel for example. The anti-reflection structure 2 of this embodiment includes a first barrier layer 21, a phase retardation film 22, a second barrier layer 23, a polarizing film 24 and a covering layer 25. The first barrier layer 21 is disposed on the display unit 1. The phase retardation film 22 is disposed on the first barrier layer 21. The second barrier layer 23 is disposed on the phase retardation film 22. The polarizing film 24 is disposed on the second barrier layer 23. The covering layer 25 is disposed on the polarizing film 24.

In more specific, the first barrier layer 21 is disposed on the display unit 1, and the other components of the anti-reflection structure 2 are disposed between the first barrier layer 21 and the covering layer 25. The polarizing film 24 is disposed between the covering layer 25 and the display unit 1. The second barrier layer 23 is disposed between the polarizing film 24 and the phase retardation film 22. The phase retardation film 22 is disposed between the second barrier layer 23 and the first barrier layer 21.

Preferably, the phase retardation film 22 is a ¼ λ retarder. The combination of the polarizing film 24 and the phase retarder film 22 can eliminate the reflection of the environmental light entering the display unit 1, thereby achieving the goal of preventing the unclear displayed image. In other words, when the environmental light enters the polarizing film 24, it will be polarized to form linear polarized light and then converted to circular polarized light by the phase retardation film 22. When the circular polarized light is reflected from the reflective electrode, the rotation direction of the circular polarized light will be converted to the opposite chirality. Besides, the reflected light will be converted to the linear polarized light by the phase retardation film 22. The direction of the output linear polarized light is perpendicular to the input linear polarized light, so it can eliminate the reflection of the reflective electrode. Accordingly, the anti-reflection structure 2 has a polarizing film 24 and a phase retardation film 22 for fixing or compensating the outputted light of the display unit 1, thereby declining the unclear display image.

In this embodiment, the first barrier layer 21 is disposed on one side of the polarizing film 24 opposite to the display unit 1, and the second barrier layer 23 is disposed on one side of the phase retardation film 22 opposite to the display unit 1. The first barrier layer 21 and the second barrier layer 23 have better water-vapor-proof and oxygen-proof effects for enhancing the water-vapor-proof and oxygen-proof abilities of the anti-reflection structure 2. The first barrier layer 21 is disposed between the phase retardation film 22 and the display unit 1, and the second barrier layer 23 is disposed between the polarizing film 24 and the phase retardation film 22. If the side of the anti-reflection structure 2 close to the display unit 1 is defined as the inner side, the covering layer 25 is located at the outer side of the anti-reflection structure 2. In addition, the polarizing film 24, the second barrier layer 23, the phase retardation film 22 and the first barrier layer 21 are arranged between the covering layer 25 and the display unit 1 from the outer side to the inner side. In this embodiment, an adhesive layer A is disposed on the other side of the first barrier layer 21 for bonding the anti-reflection structure 2 to the display unit 1.

In this embodiment, the first barrier layer 21 and the second barrier layer 23 can be made of the same material (as shown in FIGS. 1A and 1B). In other words, the first barrier layer 21 and the second barrier layer 23 of this embodiment are all the barrier layers for blocking moisture and oxygen. Preferably, the first barrier layer 21 and the second barrier layer 23 may include inorganic material such as, for example but not limited to, SiNx, SiO₂, Al₂O₃, SiON, SiCN, or any of their mixtures. The inorganic material can be formed by coating and have better water-vapor-proof and oxygen-proof effects than the organic material. In other embodiments, the first barrier layer 21 and the second barrier layer 23 can be made of hard carbon film (diamond like carbon, DLC), which can also provide good water-vapor-proof and oxygen-proof effects.

In this embodiment, the covering layer 25 can be a water-vapor-proof and oxygen-proof adhesive material such as acrylic-based thermo-curing material, acrylic-based light-curable material, epoxy resin based thermo-curing material, epoxy resin based light-curable material, silicon-based thermo-curing material, silicon-based light-curable material, or any of their mixtures. The covering layer 25 is coated on one side of the polarizing film 24 away from the display unit 1. The water-vapor-proof and oxygen-proof adhesive material is hardened so as to form the covering layer 25. The covering layer 25 is disposed at the outside of the anti-reflection structure 2. The first barrier layer 21 is disposed at one side of the phase retardation film 22, and the second barrier layer 23 is disposed at one side of the polarizing film 24. The covering layer 25, the first barrier layer 21 and the second barrier layer 23, which have water-vapor-proof and oxygen-proof effects, are separately disposed, so that the anti-reflection structure 2 itself has the water-vapor-proof and oxygen-proof effects for blocking moisture and oxygen from entering the internal space of the display device D1.

FIG. 1B is a sectional view of a display device D2 according to another embodiment of the invention. The display device D2 is equipped with a touch control function. For example, the display device D2 can further include a touch substrate 3 and a protective substrate 4. The touch substrate 3 is disposed at one side of the covering layer 25 away from the display unit 1, and the protective substrate 4 is disposed at the other side of the touch substrate 3. In other words, the protective substrate 4 is disposed at the outer side of the touch substrate 3 for protecting the touch substrate 3 and the entire display device D2. Of course, in other embodiments, the protective substrate 4 can be made of water-vapor-proof material, so it can be included in the scope of the covering layer 25.

In addition, an adhesive layer 26 can be disposed between the second barrier layer 23 and the phase retardation film 22 for bonding the polarizing film 24, the second barrier layer 23, the phase retardation film 22 and the first barrier layer 21. The covering layer 25 of this embodiment can connecting the protective substrate 4, the touch substrate 3 and the entire anti-reflection structure 2, and the anti-reflection structure 2 is disposed on the display unit 1.

Preferably, the display unit 1 is an OLED display unit, which includes a light-emitting unit 11, a substrate 12, a seal 13 and a third barrier layer 14. The substrate 12 is used to carry the display unit 1. The seal 13 is disposed at the edges of the substrate 12 and the anti-reflection structure 2, so that the substrate 12, the anti-reflection structure 2 and the seal 13 can form an accommodating space. The light-emitting unit 11 and the third barrier layer 14 are disposed in the accommodating space. The light-emitting unit 11 is disposed at one side of the substrate 12 opposite to the anti-reflection structure 2, and the third barrier layer 14 is disposed at one side of the light-emitting unit 11 opposite to the substrate 12. The material of the third barrier layer 14 can be the same as that of the first barrier layer 21 and/or the second barrier layer 23. In this embodiment, the display unit 1 further includes a packaging layer 15 disposed at one side of the third barrier layer 14 opposite to the light-emitting unit 11. In other words, the light-emitting unit 11, the third barrier layer 14 and the packaging layer 15 are disposed in sequence from the substrate 12 to the anti-reflection structure 2. Herein, the packaging layer 15 and the seal 13 can be made of the same material. Accordingly, the seal 13 can bond the anti-reflection structure 2 and the substrate 12, and the light-emitting unit 11, the third barrier layer 14 and the packaging layer 15 are disposed in sequence and located in the accommodating space formed by the substrate 12, the anti-reflection structure 2 and the seal 13.

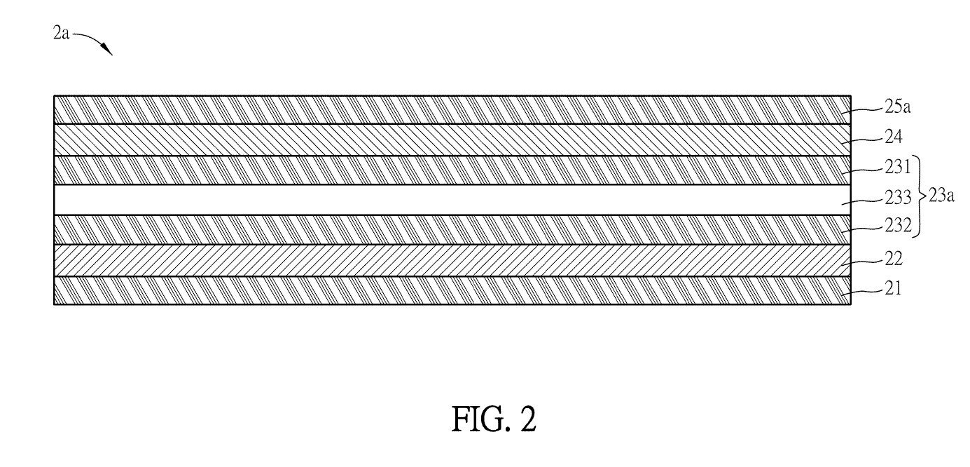

FIG. 2 is a sectional view of an anti-reflection structure 2a according to another embodiment of the invention. As shown in FIG. 2, the material of the covering layer 25a is the same that of the first barrier layer 21. Compared to the anti-reflection structure 2 of FIGS. 1A and 1B, the second barrier layer 23a of the anti-reflection structure 2a of this embodiment further includes a first sub-barrier layer 231, a second sub-barrier layer 232 and an adhesive layer 233, which is disposed between the first sub-barrier layer 231 and the second sub-barrier layer 232 for bonding the first sub-barrier layer 231 and the second sub-barrier layer 232. The first barrier layer 21, the first sub-barrier layer 231 and the second sub-barrier layer 232 can be made of the same material, and they can all be the above-mentioned barrier layer for blocking moisture. In more specific, the covering layer 25a, the first barrier layer 21, the first sub-barrier layer 231 and the second sub-barrier layer 232 can include inorganic material, preferably diamond like carbon (DLC), for providing good water-vapor-proof and oxygen-proof effects. The covering layer 25a and the first sub-barrier layer 231 are disposed at two sides of the polarizing film 24, respectively, and the first sub-barrier layer 231 can be formed on the polarizing film 24 by coating. The second sub-barrier layer 232 and the first sub-barrier layer 231 are disposed at two sides of the phase retardation film 22, respectively, and the second sub-barrier layer 232 can be formed on the phase retardation film 22 by coating. In other words, the four layers of barrier layers can be formed at both sides of the phase retardation film 22 and the polarizing film 24 so as to form sandwich structures. The two sandwich structures can be bonded by an adhesive layer 233.

In the reflection structure 2a of this embodiment, the both sides of the polarizing film 24 and the phase retardation film 22 are configured with barrier layers (the covering layer 25a, the first barrier layer 21, the first sub-barrier layer 231 and the second sub-barrier layer 232). Accordingly, this the anti-reflection structure 2a itself has the water-vapor-proof and oxygen-proof effects for blocking moisture from entering the display device through the display surface, thereby protecting the display unit from damage by the moisture.

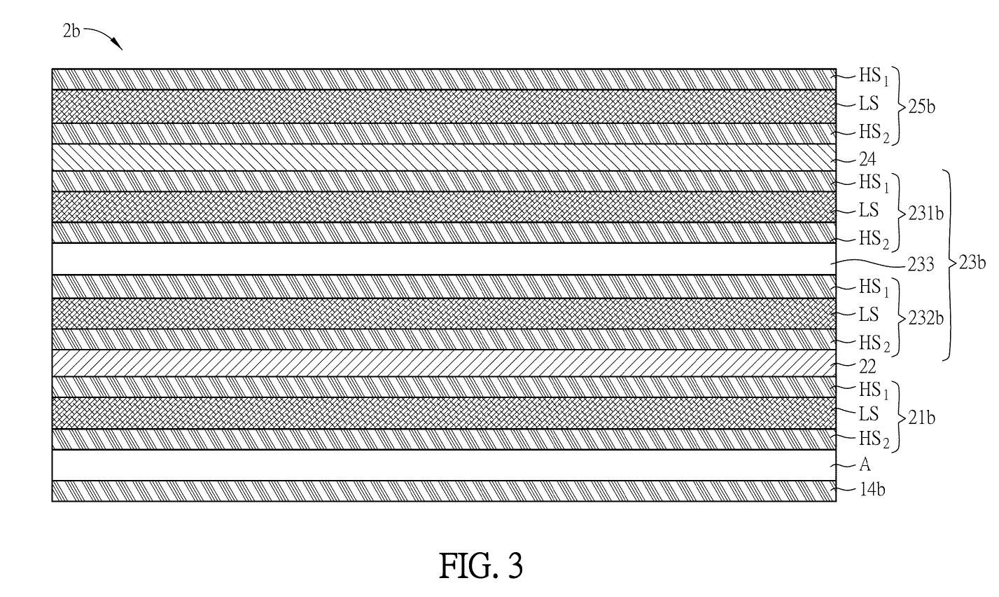

FIG. 3 is a sectional view of an anti-reflection structure 2b according to another embodiment of the invention. Compared with the anti-reflection structure 2a of FIG. 2, the first barrier layer 21b of the anti-reflection structure 2b is formed by a higher stress layer HS₁ and a lower stress layer LS, and the second barrier layer 23b of the anti-reflection structure 2b is formed by a higher stress layer HS₂ and a lower stress layer LS. Herein, the stress values of the higher stress layers HS₁ and HS₂ are greater than 100 MPa. In more specific, the covering layer 25b, the first barrier layer 21b, the first sub-barrier layer 231b and the second sub-barrier layer 232b can be multilayer structures. In this embodiment, they can be three layer structures including one lower stress layer LS and two higher stress layers HS₁ and HS₂. The lower stress layer LS is disposed between the higher stress layers HS₁ and HS₂. In this embodiment, the higher stress layers HS₁ and HS₂ are made of inorganic material, while the lower stress layer LS is made of organic material, such as acrylic-based material, epoxy resin based material, silicon-based material and various organic polymers.

In general, the inorganic film (the higher stress layers HS₁ and HS₂) has larger internal stress, and its water-vapor-proof and oxygen-proof abilities are greater than the organic film. On the contrary, the organic film (the lower stress layer LS) has smaller internal stress and better flexibility. If the internal stress is too high, the inorganic film may crack, which will lead to the decrease of the water-vapor-proof ability. The stacked structure configured by interlaced organic film and inorganic film can release the internal stress of the inorganic film, so that the stacked structure will not crack as the high stress is accumulated. In this embodiment, the higher stress layers HS₁ and HS₂ with better water-vapor-proof and oxygen-proof abilities are disposed at two sides of the flexible lower stress layer LS. Accordingly, the covering layer 25b, the first barrier layer 21b, the first sub-barrier layer 231b and the second sub-barrier layer 232b can protect the polarizing film 24 and the phase retardation film 22, provide better water-vapor-proof and oxygen-proof effects to the anti-reflection structure 2b, and maintain the flexibility of the anti-reflection structure 2b.

Similarly, the second barrier layer 23b further includes an adhesive layer 233 for bonding the first sub-barrier layer 231b and the second sub-barrier layer 232b. Accordingly, the adhesive layer 233 is disposed between the higher stress layers HS₁ and HS₂. This configuration can also form the sandwich structure composed of the covering layer 25b, the polarizing film 24 and the first sub-barrier layer 231b and the sandwich structure composed of the second sub-barrier layer 232b, the phase retardation film 22 and the first barrier layer 21b. These sandwich structures are bonded by the adhesive layer 233. The details of the sandwich structure can be referred to the above examples, so they are not repeated here.

In addition, the anti-reflection structure 2b of this embodiment further includes an adhesive layer A and a third barrier layer 14b disposed at the other side of the first barrier layer 21b. The adhesive layer A can bond the higher stress layer HS₂ of the first barrier layer 21b and the third barrier layer 14b. The third barrier layer 14b is a part of the display unit 1, and it can be directly disposed at one side of the display unit (not shown). Otherwise, as shown in FIG. 1A, the third barrier layer A can be disposed in the accommodating space formed by the substrate 12 and the seal 13. In this embodiment, the third barrier layer 14b is an inorganic film. Of course, in other embodiments, the third barrier layer 14b can be a multilayer structure as mentioned above (a three layer structure including two higher stress layers HS₁ and HS₂ and a lower stress layer LS disposed between the higher stress layers HS₁ and HS₂). The third barrier layer 14b can provide additional water-vapor-proof and oxygen-proof effects for further protecting the display unit 1.

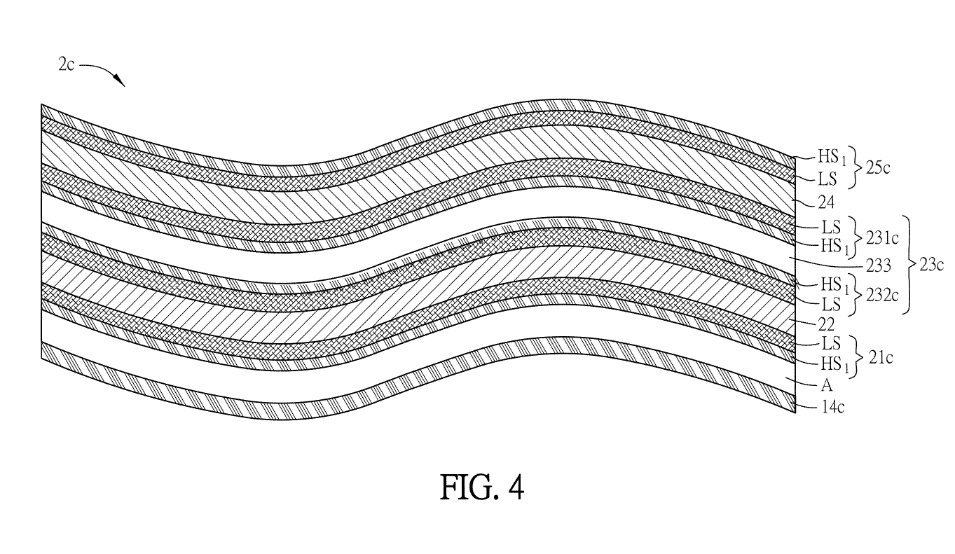

FIG. 4 is a sectional view of an anti-reflection structure 2c according to another embodiment of the invention. Compared with the anti-reflection structure 2b of FIG. 3, each of the covering layer 25c, the first sub-barrier layer 231c, the second sub-barrier layer 232c and the first barrier layer 21c of the anti-reflection structure 2c of FIG. 4 can be a two-layer structure including a higher stress layer HS₁ and a lower stress layer LS. In this embodiment, one side of the lower stress layer LS of the covering layer 25c is disposed on the surface of the polarizing film 24, and the higher stress layer HS₁ of the covering layer 25c is disposed at the other side of the lower stress layer LS. One side of the lower stress layer LS of the first sub-barrier layer 231c is disposed on the surface of the polarizing film 24, and the higher stress layer HS₁ of the first sub-barrier layer 231c is disposed at the other side of the lower stress layer LS. One side of the lower stress layer LS of the second sub-barrier layer 232c is disposed on the surface of the phase retardation film 22, and the higher stress layer HS₁ of the second sub-barrier layer 232c is disposed at the other side of the lower stress layer LS. One side of the lower stress layer LS of the first barrier layer 21c is disposed on the surface of the phase retardation film 22, and the higher stress layer HS₁ of the first barrier layer 21c is disposed at the other side of the lower stress layer LS. This configuration can protect the polarizing film 24 and the phase retardation film 22 from the damage caused by the higher stress layers HS₁. In other words, the lower stress layers LS are disposed at the inner sides, which are closed to the polarizing film 24 or the phase retardation film 22, and the higher stress layers HS₁ with better water-vapor-proof and oxygen-proof effects are disposed at the outer sides. This configuration can also provide good water-vapor-proof and oxygen-proof effects. Besides, the multilayer structure includes a lower stress layer LS with better flexibility and a higher stress layer HS₁, which means the contained lower stress layer LS and higher stress layer HS₁ are in a ratio of 1:1, so that the anti-reflection structure 2c can have better flexibility. Similarly, the second barrier layer 23c further includes an adhesive layer 233 for bonding the first sub-barrier layer 231c and the second sub-barrier layer 232c. Accordingly, the adhesive layer 233 is disposed between two higher stress layers H5₁ and H5₂. The details of the formed sandwich structures (one sandwich structure is composed of the covering layer 25c, the polarizing film 24 and the first sub-barrier layer 231c, and the other sandwich structure is composed of the second sub-barrier layer 232c, the phase retardation film 22 and the first barrier layer 21c) can be referred to the above-mentioned embodiment, so they are not repeated here.

In addition, the anti-reflection structure 2c of this embodiment further includes an adhesive layer A and a third barrier layer 14c disposed at the other side of the first barrier layer 21c. The adhesive layer A can bond the higher stress layer H5₁ of the first barrier layer 21c and the third barrier layer 14c so as to achieve the desired better water-vapor-proof and oxygen-proof effects. The third barrier layer 14c is a part of the display unit, and it can be directly disposed at one side of the display unit (not shown). The details of the adhesive layer A and a third barrier layer 14c can be referred to the previous embodiments, so they are not repeated here.

As shown in FIG. 1, any one of the covering layer 25, the first barrier layer 21, the second barrier layer 23 and the third barrier layer 14 can individually be a single-layer structure or a multilayer structure, and this invention is not limited. Preferably, the thicknesses of the first barrier layer 21 and the second barrier layer 23 are between 0.1 μm and 5 μm. In addition, the materials (e.g. the above-mentioned DLC) of the first barrier layer 21, the second barrier layer 23 and the third barrier layer 14 all have good barrier property. Accordingly, even these barrier layers are multilayer structures, the entire thickness of the anti-reflection structure can be properly controlled, and the anti-reflection structure can still have good flexibility.

In addition, this invention further discloses an anti-reflection structure including a first barrier layer, a phase retardation film, a second barrier layer, a polarizing film and a covering layer. The first barrier layer is disposed on a display unit. The phase retardation film is disposed on the first barrier layer. The second barrier layer is disposed on the phase retardation film. The polarizing film is disposed on the second barrier layer. The covering layer is disposed on the polarizing film. The details and connections of the all components of the anti-reflection structure can be referred to the above embodiments, so the detailed descriptions thereof will be omitted here.

To sum up, in the anti-reflection structure, the first barrier layer is disposed on one side of the phase retardation film opposite to the display unit, and the second barrier layer is disposed on one side of the polarizing film opposite to the display unit. In more detailed, the first barrier layer is disposed on a display unit, the phase retardation film is disposed on the first barrier layer, the second barrier layer is disposed on the phase retardation film, the polarizing film is disposed on the second barrier layer, and the covering layer is disposed on the polarizing film. In other words, the polarizing film, the second barrier layer, the phase retardation film and the first barrier layer are configured between the covering layer and the display unit so as to form the anti-reflection structure with multiple water-vapor-proof and oxygen-proof structures (including the covering layer, the first barrier layer and the second barrier layer). The first and second barrier layers are disposed on the polarizing film and the phase retardation film, respectively, so that it is possible to enhance the water-vapor-proof and oxygen-proof abilities of the anti-reflection structure. Moreover, the anti-reflection structure is disposed at one side of the display unit, so that it can prevent moisture and oxygen from entering the internal space of the display unit through the display surface, thereby protecting the internal components of the display unit from damages.

In addition, the polarizing film and the phase retardation film of the anti-reflection structure can adjust the polarizing direction and phase difference of the light entering the display unit, thereby blocking the reflection of the environmental light so as to decline the unclear issue of the displayed image.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A display device, comprising:
a display unit; and
an anti-reflection structure disposed on the display unit, wherein the anti-reflection structure comprises:
a first barrier layer disposed on the display unit,
a phase retardation film disposed on the first barrier layer,
a second barrier layer disposed on the phase retardation film,
a polarizing film disposed on the second barrier layer, and
a covering layer disposed on the polarizing film.

2. The display device of claim 1, wherein the first barrier layer and the second barrier layer are made of inorganic material.

3. The display device of claim 2, wherein at least one of the first barrier layer and the second barrier layer is made of diamond-like carbon (DLC).

4. The display device of claim 1, wherein the second barrier layer comprises a first sub-barrier layer, a second sub-barrier layer and an adhesive layer disposed between the first sub-barrier and the second sub-barrier.

5. The display device of claim 4, wherein the first sub-barrier layer is formed on the polarizing film, and the second sub-barrier layer is formed on the phase retardation film.

6. The display device of claim 1, wherein the first barrier layer comprises a higher stress layer and a lower stress layer.

7. The display device of claim 6, wherein the higher stress layer is made of inorganic material, and the lower stress layer is made of organic material.

8. The display device of claim 1, wherein the second barrier layer comprises a higher stress layer and a lower stress layer.

9. The display device of claim 8, wherein the higher stress layer is made of inorganic material, and the lower stress layer is made of organic material.

10. The display device of claim 1, wherein the display unit is an organic light emitting diode display unit.

11. The display device of claim 1, wherein the thickness of the first barrier layer and the second barrier layer respectively is between 0.1 μm and 5 μm.

12. An anti-reflection structure, comprising:
a first barrier layer;
a phase retardation film disposed on the first barrier layer;
a second barrier layer disposed on the phase retardation film;
a polarizing film disposed on the second barrier layer; and
a covering layer disposed on the polarizing film.
